(19) United States
(12) Patent Application Publication
(10) Pub. No.: US 2010/0146349 A1
(43) Pub. Date: Jun. 10, 2010

(54) Semiconductor integrated circuit including logic circuit having scan path and test circuit for conducting scan path test

(75) Inventor: Masao Asou, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/591,885

(22) Filed: Dec. 3, 2009

(30) Foreign Application Priority Data
Dec. 10, 2008 (JP) 2008-314766

(51) Int. Cl. G01R 31/3177; G06F 11/25

(52) U.S. Cl. 714/731; 714/E11.155

(57) ABSTRACT

A semiconductor integrated circuit is configured which has a logic circuit having scan path flip-flops and a test circuit which executes a scan path test. The test circuit includes a clock control circuit and a scan enable control signal generation circuit. The scan enable control signal generation circuit receives a clock-on information signal output from the clock control circuit and supplies a scan enable control signal to another clock control circuit. The other clock control circuit identifies the value of a scan enable signal on the basis of the scan enable control signal. At this time, the scan path flip-flops output fixed values from data output terminals according to the value of the scan enable signal.

### INCORPORATION BY REFERENCE

This application is based upon and claims the benefit of priority from Japanese Patent Application No. 2008-314766 which was filed on Dec. 10, 2008, the disclosure of which is incorporated herein in its entirety by reference.

### BACKGROUND OF THE INVENTION

1. Field of the Invention

The present invention relates to a semiconductor integrated circuit and a method of testing the semiconductor integrated circuit.

2. Description of Related Art

A system LSI is a large-scale circuit in which a logic core, a memory core, an analog core and the like are mounted. There is a demand for suitably executing a function test on a system LSI and ensuring adequate test quality. In system LSIs in recent years, with the trends of miniaturization and higher functionality, the number of mounted cores has markedly increased and the circuit scale has been markedly enlarged. The increase in testing time resulting from this is a consideration. Techniques provided in consideration of such a problem to make a test easier are known. For example, Patent document 1 (Japanese Patent Laid-Open No. 2003-344504) discloses a scan flip-flop circuit having an output terminal Q and an output terminal SO provided separately from each other and used for a logic circuit and for a scan flip-flop circuit in the next stage, respectively. In the scan flip-flop circuit, the output at the output terminal SO for the scan flip-flop circuit in the next stage is fixed during ordinary operation. The technique described in patent document achieves, by means of such a configuration and operation, high-speed operation and a low power consumption during ordinary operation.

In recent years, many faults which cannot be detected by the tests intended for detecting single degenerative faults have appeared with the progress to finer design rules for LSI manufacturing processes. Such faults can be detected only by tests intended for detecting bridge faults and delay faults. A demand has therefore arisen for a great multiplicity of test patterns for a plurality of such faults in order to realize high-quality tests. From an increase of such test patterns, an increase in testing cost results. Attempts to reduce the test time have been actively made to control costs.

Methods for reducing the test time are typically a method of increasing the test rate and a method of simultaneously testing as many as possible places in portion of an LSI. If operations in many places are simultaneously performed, then there is a risk of an extremely large increase in instantaneous power consumption (peak power consumption) at the time of testing. In particular, in a semiconductor integrated circuit such as a system LSI in which circuits of a multiplicity of kinds extremely large in number are housed in one chip, there is a possibility of a peak power consumption at the time of testing being extremely high.

While a power supply design is ordinarily made with respect to power consumption in actual use of a device, no power supply design factoring in an increase in peak power at the time of testing is being practiced. The possibility of internal circuits in a semiconductor integrated circuit being simultaneously operated as at the time of testing is substantially zero in actual use. Therefore, the value of peak power in actual use is not so high in ordinary cases. As a result, in some case, a semiconductor integrated circuit not factoring in such a peak power consumption at the time of testing fails to operate normally or is damaged during a scan test. Thus, a technique for reducing peak power consumption during a scan test is known. For example, Patent document 2 (Japanese Patent Laid-Open No. 2001-59856) describes a technique to devise means for setting dispersed time intervals at which circuits in a semiconductor integrated circuit are operated when a scan test is made on the semiconductor integrated circuit, while limiting an increase in the time during which a tester is used.

FIG. 1 is a circuit diagram showing the configuration of a system LSI described in patent document 2. In the technique described in patent document 2, the system LSI is provided with a plurality of flip-flop circuits (flip-flop circuits 111A to 111F) and a combination circuit 110. Referring to FIG. 1, internal portions of the combination circuit 110 are divided into three groups (first group X, second group Y, third group Z). FIG. 2 is a diagram showing changes in test mode in the system LSI described in patent document 2. Referring to FIG. 2, outputs at Q terminals are fixed by shifting timing with respect to the flip-flop circuits corresponding to the divided groups (first group X, second group Y, third group Z). An operation in a shift mode is performed while the Q terminals of the flip-flop circuits are fixed. After the completion of the operation in the shift mode, hold cancellation and a capture operation are performed with respect to each of the flip-flop circuits corresponding to the divided groups (first group X, second group Y, third group Z). Hold cancellation is made when one clock is H level, the capture operation is performed when the clock is L level. Alternatively, hold cancellation is made in order of the groups (first group X, second group Y, third group Z) and the capture operation to take in a data signal D is performed in order of the groups (first group X, second group Y, third group Z).

According to the scan test method in this example of the related art, the state in the combination circuit 110 is held before transition to the shift mode operation and, therefore, an increase in power consumption due to change of each element in the combination circuit 110 simultaneous with a shift of a scan test signal DT sent to the flip-flop circuits 111A to 111F in the shift mode operation each time the scan test signal DT is shifted can be limited. After dividing the internal portions of the combination circuit 110 into the plurality of groups and making hold cancellation with respect to each of the plurality of groups, holding is again performed and the capture operation is thereafter performed. In the system LSI in the patent document 2, an increase in peak power consumption due to changes in the logic circuit according to the scan test signal during shift operation can be limited by means of the configuration and operation described above. Further, a peak power consumption during holding operation, hold canceling operation, capture operation and the like can be reduced.

### SUMMARY

In the method of testing in the system LSI of a related art, internal portions of the combination circuit are divided into a plurality of groups; after hold cancellation is made with respect to each of the plurality of groups, the holding operation is again performed; and the capture operation is thereafter performed. A cycle in which hold cancellation and holding operation are performed with respect to each group is therefore required in the capture period. Further, in the hold canceling operation, cancellation is always made even with respect to some of the groups with no need for cancellation according to some test pattern, because details of the test pattern are not considered. Thus, there is a problem that the number of cycles required in the period in which the capture operation is performed is increased and the testing time for the scan test is increased.

A semiconductor integrated circuit of an exemplary aspect of the present invention includes a logic circuit (65) having a plurality of scan path flip-flops constituting a scan path, and a test circuit (70) which executes a scan path test in correspondence with the scan path. The test circuit (70) includes a clock control circuit (80) which controls a scan clock to be supplied to the scan path flip-flop, and a scan enable control signal generation circuit (13) which supplies a scan enable control signal for controlling a scan enable signal. The scan enable control signal generation circuit (13) receives a clock-on information signal output from the clock control circuit (80) (80a) and generates a scan enable control signal to be supplied to another clock control circuit (80) (80b). The other clock control circuit (80) (80b) identifies the value of the scan enable signal on the basis of the scan enable control signal. The scan path flip-flops receive the scan clock and the scan enable signal and output fixed values from data output terminals (64) according to the value of the scan enable signal.

Based on the exemplary aspect, a reduction in number of cycles in a capture period in a scan test is achieved.

It is noted that the numbers in the exemplary aspect is added to clarify the correspondence between claim scope and the specification. Therefore, the numbers are not intended for interpreting the specification into claims.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 is a circuit diagram showing a configuration of a system LSI of a related art;

FIG. 2 is a diagram showing changes in test mode in the system LSI of the related art;

FIG. 3 is a block diagram showing a configuration of a semiconductor integrated circuit 1 in an exemplary embodiment of a present invention;

FIG. 4 is a block diagram showing a configuration of a logic circuit 65;

FIG. 5 is a block diagram showing a configuration of a scan flip-flop disposed in the logic circuit 65;

FIG. 6 is a block diagram showing a configuration of a first clock control circuit 80a;

FIG. 7 is a block diagram showing a configuration of a test pattern generation tool in the exemplary embodiment;

FIG. 8 is a block diagram showing a configuration of a scan enable control signal generation circuit preparation tool in the exemplary embodiment;

FIG. 9 is a flowchart showing a procedure for test pattern generation processing executed by the test pattern generation tool in the exemplary embodiment;

FIG. 10 is a flowchart showing details of a procedure for clock group preparation processing;

FIG. 11 is a flowchart showing details of a procedure for clock relation extraction processing;

FIG. 12 is a flowchart showing details of a procedure for clock search processing;

FIG. 13 is a table showing a configuration of clock relation information 23 usable in the exemplary embodiment;

FIG. 14 is truth table corresponding to the operation of a scan enable control signal generation circuit 13 usable in the exemplary embodiment;

FIG. 15 is a circuit diagram showing connections between a test circuit 70 and the logic circuit 65;

FIG. 16 is a diagram showing a configuration of a scan pattern when a test pattern preparation method in the exemplary embodiment is applied; and

FIG. 17 is a timing chart of a first scan pattern 59 and a second scan pattern 60.

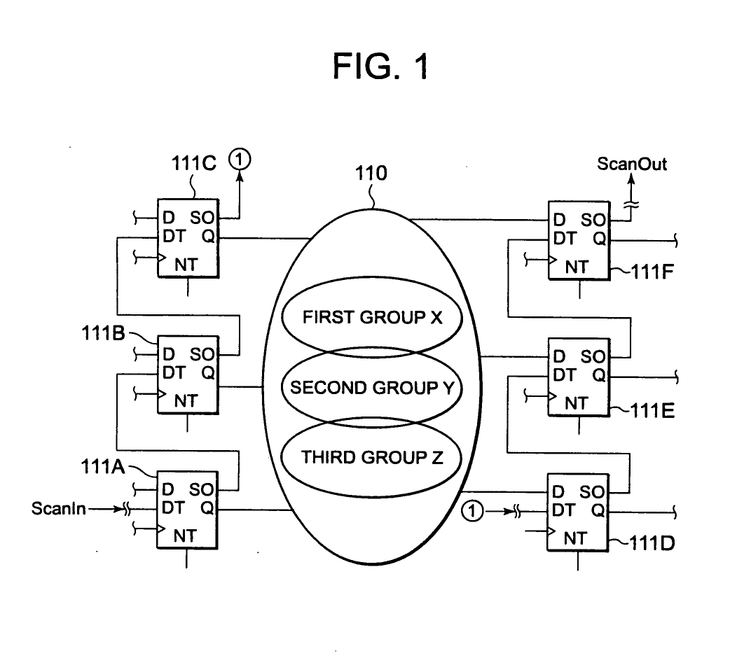

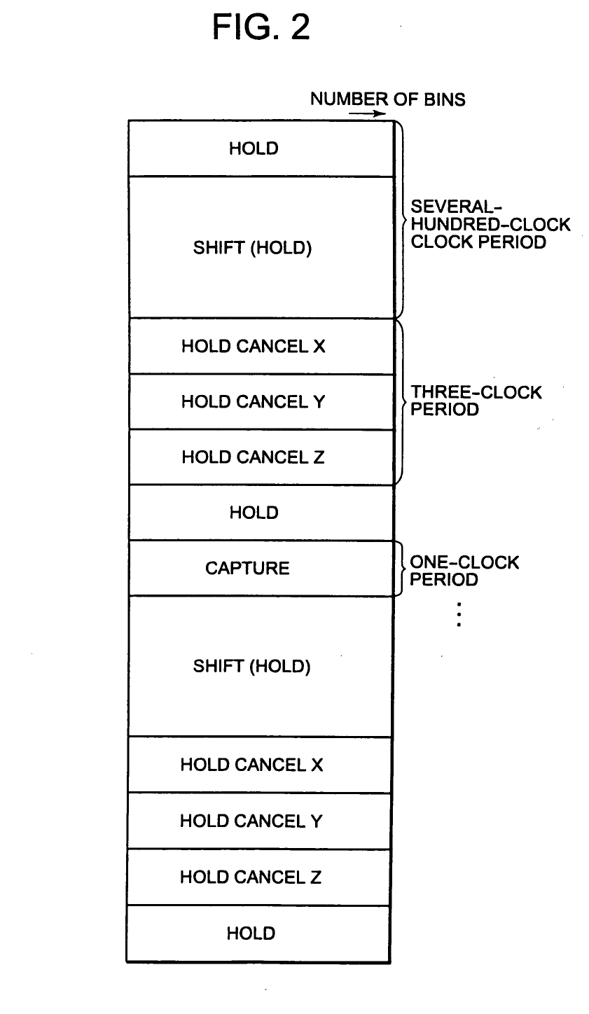

### DETAILED DESCRIPTION OF THE EXEMPLARY EMBODIMENTS

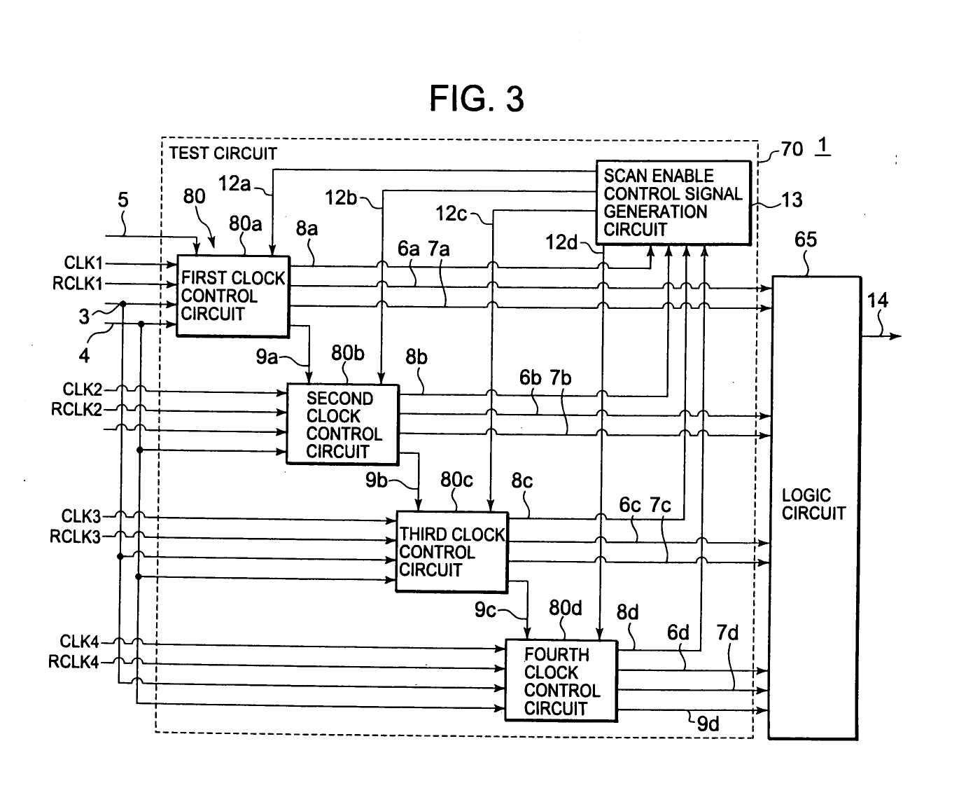

FIG. 3 is a block diagram showing a configuration of a semiconductor integrated circuit 1 in an exemplary embodiment of the present invention. The semiconductor integrated circuit 1 has a logic circuit 65 and a test circuit 70. The test circuit 70 includes a plurality of clock control circuits (first to fourth clock control circuits 80a to 80d) and a scan enable control signal generation circuit 13. In some case, in the embodiment described below, the plurality of clock control circuits (first to fourth clock control circuits 80a to 80d) are described as clock control circuits 80 without being discriminated from each other. In the test circuit 70, there is no limit to the number of clock control circuits 80. In this specification, for ease of understanding of the invention in the present application, the test circuit 70 provided with the first to fourth clock control circuits 80a to 80d is described.

Referring to FIG. 3, clock output signals 6 (first to fourth clock output signals 6a to 6d) supplied from the clock control circuits 80 (first to second clock control circuits 80a to 80b) provided in each clock line and scan enable signals 7 (first to fourth scan enable signals 7a to 7d) are input to the logic circuit 65, and the logic circuit 65 outputs a data output signal 14.

The first clock control circuit 80a, the second clock control circuit 80b, the third clock control circuit 80c and the fourth clock control circuit 80d are respectively inserted in the clock lines between clock terminals and the logic circuit 65. A first scan clock signal CLK1 (also referred to as “scan clock signal” below in some case), which is a clock at the time of a scan test, a first ordinary clock signal RCLK1 (also referred to as “ordinary clock signal” below in some case), which is a clock in an ordinary mode, a scan enable input signal 3, a test mode signal 4 and a scan-in signal 5 are input to the first clock control circuit 80a. The first clock output signal 6a, the first scan enable signal 7a, a first clock-on information signal 8a and a first scan-out signal 9a are output from the first clock control circuit 80a.

The first scan-out signal 9a output from the first clock control circuit 80a is supplied to the second clock control circuit 80b. A second scan clock signal CLK2, a second ordinary clock signal RCLK2, the scan enable input signal 3 and the test mode signal 4 are also supplied to the second clock control circuit 80b. From the second clock control circuit 80b, the second clock output signal 6b, the second scan enable signal 7b, a second clock-on information signal 8b and a second scan-out signal 9b are output.

Similarly, the second scan-out signal 9b output from the second clock control circuit 80b is supplied to the third clock control circuit 80c. A third scan clock signal CLK3, a third ordinary clock signal RCLK3, the scan enable input signal 3 and the test mode signal 4 are also supplied to the third clock control circuit 80c. From the third clock control circuit 80c, the third clock output signal 6c, the third scan enable signal 7c, a third clock-on information signal 8c and a third scan-out signal 9c are output.

Also, the third scan-out signal 9c output from the third clock control circuit 80c is supplied to the fourth clock control circuit 80d. A fourth scan clock signal CLK4, a fourth ordinary clock signal RCLK4, the scan enable input signal 3 and the test mode signal 4 are also supplied to the fourth clock control circuit 80d. From the fourth clock control circuit 80d, the fourth clock output signal 6d, the fourth scan enable signal 7d, a fourth clock-on information signal 8d and a fourth scan-out signal 9d are output.

The first clock-on information signal 8a output from the first clock control circuit 80a, the second clock-on information signal 8b output from the second clock control circuit 80b, the third clock-on information signal 8c output from the third clock control circuit 80c and the fourth clock-on information signal 8d output from the fourth clock control circuit 80d are supplied to the scan enable control signal generation circuit 13. The scan enable control signal generation circuit 13 outputs a first scan enable control signal 12a, a second scan enable control signal 12b, a third scan enable control signal 12c and a fourth scan enable control signal 12d on the basis of the first clock-on information signal 8a, the second clock-on information signal 8b, the third clock-on information signal 8c and the fourth clock-on information signal 8d.

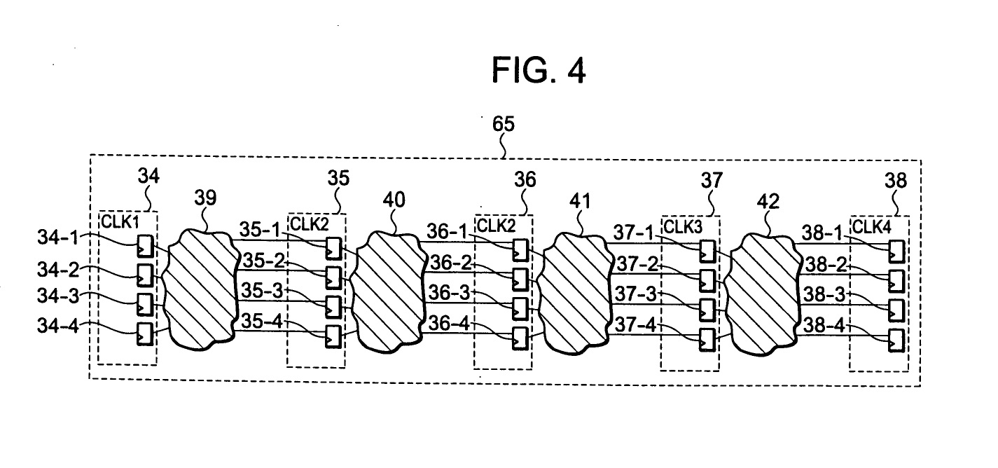

FIG. 4 is a block diagram showing a configuration of the logic circuit 65. The logic circuit 65 has a first flip-flop group 34, a second flip-flop group 35, a third flip-flop group 36, a fourth flip-flop group 37 and a fifth flip-flop group 38. The logic circuit 65 also has a first combination circuit 39, a second combination circuit 40, a third combination circuit 41 and a fourth combination circuit 42.

The first flip-flop group 34 operates by the first scan clock signal CLK1. The second flip-flop group 35 and the third flip-flop group 36 operate by the second scan clock signal CLK2. The fourth flip-flop group 37 operates by the third scan clock signal CLK3. The fifth flip-flop group 38 operates by the fourth scan clock signal CLK4. The first combination circuit 39 is disposed between the first flip-flop group 34 and the second flip-flop group 35. The second combination circuit 40 is disposed between the second flip-flop group 35 and the third flip-flop group 36. The third combination circuit 41 is disposed between the third flip-flop group 36 and the fourth flip-flop group 37. The fourth combination circuit 42 is disposed between the fourth flip-flop group 37 and the fifth flip-flop group 38.

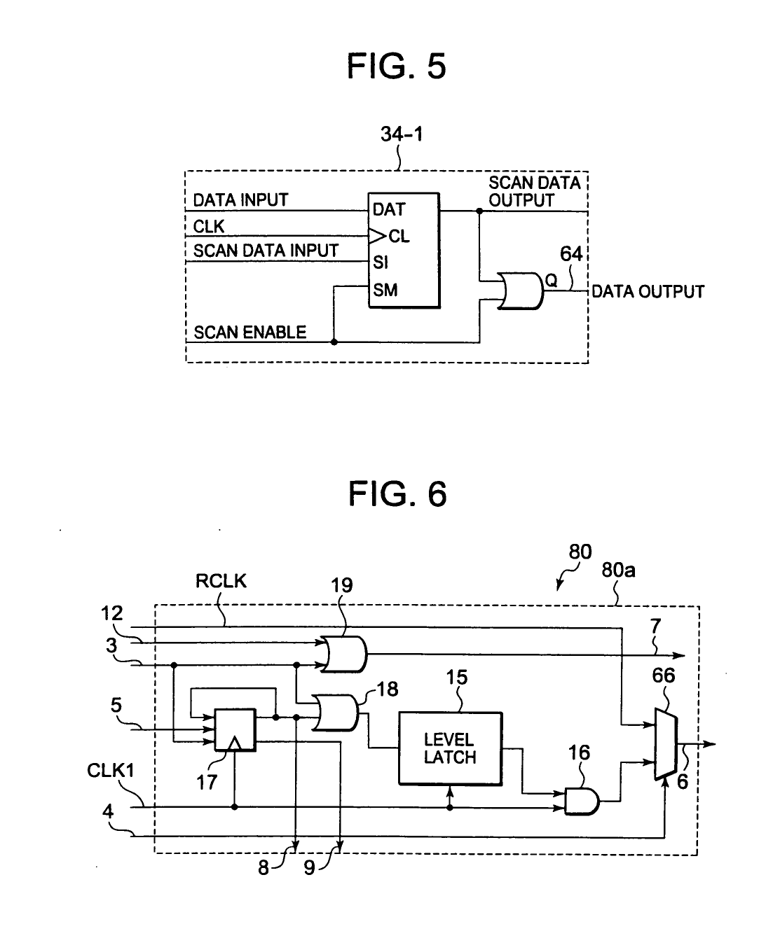

FIG. 5 is a block diagram showing a configuration of a scan flip-flop disposed in the logic circuit 65. The scan flip-flop has a data output terminal 64, and an output at the data output terminal 64 is fixed by the scan enable signal 7.

FIG. 6 is a block diagram showing a configuration of the first clock control circuit 80a. The first clock control circuit 80a has a flip-flop 17, a level latch 15, an AND circuit 16, an OR circuit 18, an OR circuit 19 and a multiplexer 66. The OR circuit 19 outputs the first scan enable signal 7a in response to the first scan enable control signal 12a and the scan enable input signal 3. The flip-flop 17 receives the scan enable input signal 3 and the scan-in signal 5 and outputs the first clock-on information signal 8a and the first scan-out signal 9a on the basis of the scan enable input signal 3 and the scan-in signal 5. The first scan clock signal CLK1 is supplied to a clock terminal of the flip-flop 17. The first scan-out signal 9a, the second scan-out signal 9b and the third scan-out signal 9c are input, in place of the scan-in signal 5, to the second clock control circuit 80b, the third clock control circuit 80c and the fourth clock control circuit 80d, respectively. In other respects, the configuration of each of the second clock control circuit 80b, the third clock control circuit 80c and the fourth clock control circuit 80d is the same as that of the first clock control circuit 80a.

The second clock control circuit 80b receives the second scan clock signal CLK2 and the second ordinary clock signal RCLK2 and outputs the second clock-on information signal 8b and the second scan-out signal 9b on the basis of the second scan clock signal CLK2 and the second ordinary clock signal RCLK2. The third clock control circuit 80c receives the third scan clock signal CLK3 and the third ordinary clock signal RCLK3 and outputs the third clock-on information signal 8c and the third scan-out signal 9c on the basis of the third scan clock signal CLK3 and the third ordinary clock signal RCLK3. The fourth clock control circuit 80d receives the fourth scan clock signal CLK4 and the fourth ordinary clock signal RCLK4 and outputs the fourth clock-on information signal 8d and the fourth scan-out signal 9d on the basis of the fourth scan clock signal CLK4 and the fourth ordinary clock signal RCLK4.

As shown in FIG. 6, the first ordinary clock signal RCLK1 is output to the first clock output signal 6a when the test mode signal 4 is low level, and the first scan clock signal CLK1 is output to the first clock output signal 6a through the value of the level latch 15 and the AND circuit 16 when the test mode signal 4 is high level. When the scan enable input signal 3 is high level, high level is input to the level latch 15. When the scan enable input signal 3 is low level, an output from the flip-flop 17 is input to the level latch 15. The output from the flip-flop 17 is also output to the first clock-on information signal 8a. With the first scan enable signal 7a, a function to output a value as a result of processing of the first scan enable control signal 12a and the scan enable input signal 3 in the OR circuit 19 is realized.

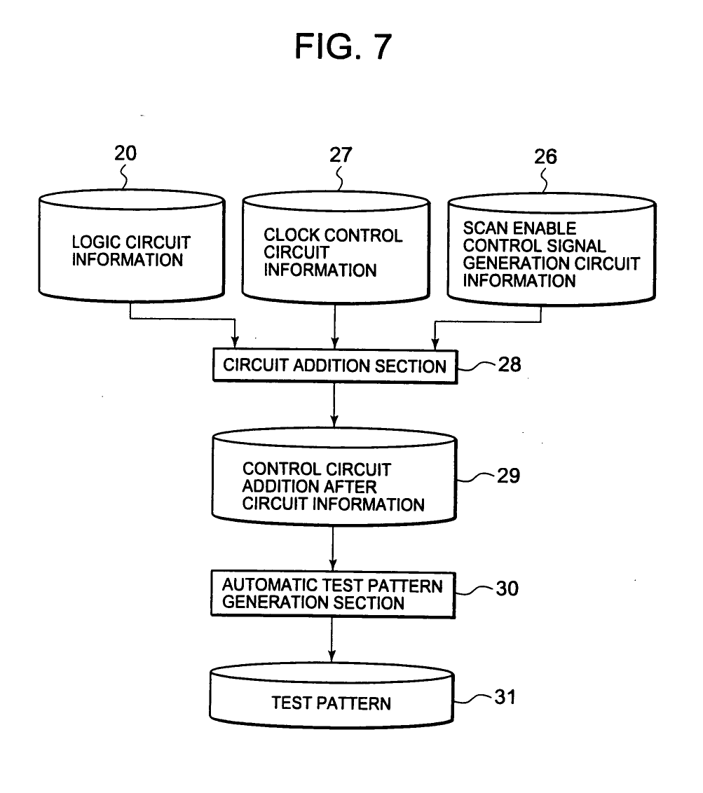

FIG. 7 is a block diagram showing a configuration of a test pattern generation tool in the exemplary embodiment. The test pattern generation tool has a circuit addition section 28 and an automatic test pattern generation section 30. The circuit addition section 28 receives clock control circuit information 27, scan enable control signal generation circuit information 26 and logic circuit information 20 and outputs control circuit addition after circuit information 29. The automatic test pattern generation section 30 receives the control circuit addition after circuit information 29 output from the circuit addition section 28 and prepares a test pattern 31 on the basis of the control circuit addition after circuit information 29.

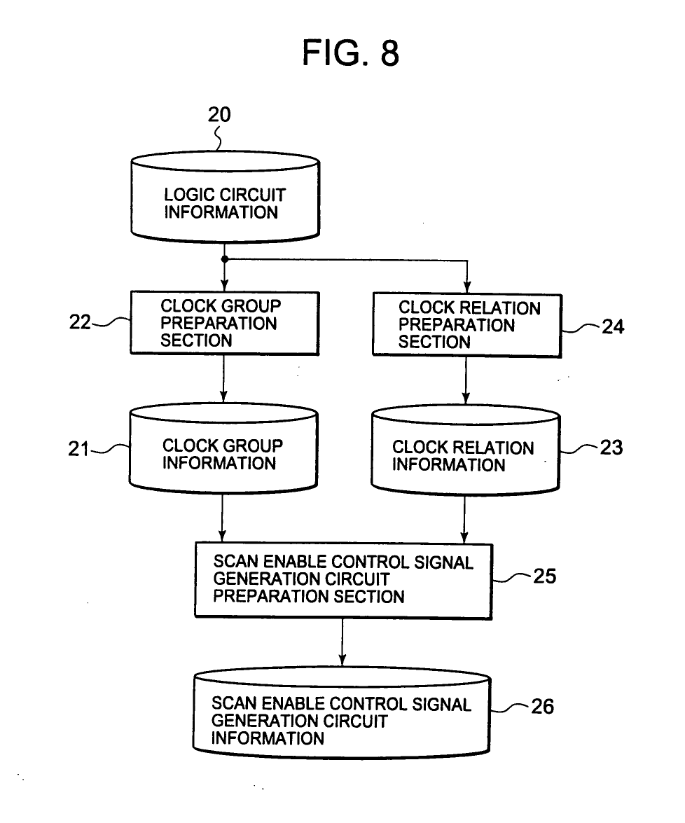

FIG. 8 is a block diagram showing a configuration of a scan enable control signal generation circuit preparation tool in the exemplary embodiment. The scan enable control signal generation circuit preparation tool has a clock group preparation section 22, a clock relation preparation section 24 and a scan enable control signal generation circuit preparation section 25. The clock group preparation section 22 receives the logic circuit information 20 and prepares clock group information 21 on the basis of the logic circuit information 20. The clock relation preparation section 24 receives the logic circuit information 20 and prepares clock relation information 23 on the basis of the logic circuit information 20. The scan enable control signal generation circuit preparation section 25 receives the clock group information 21 and the clock relation information 23 and prepares, on the basis of these sorts of information, scan enable control signal generation circuit information 26 indicating clock lines used in the pattern concerned.

As shown in FIG. 8, a combination of clocks in the test pattern permitted to be on at a time is stored in the clock group information 21. A clock line name necessary at the time of testing the logic circuit 65 in each clock line is stored in the clock relation information 23 with respect to each clock line. In the scan enable control signal generation circuit, each input signal indicates the value of the clock, high level designating application of the clock, low level designating non-application of the clock. There is a case of all the clock lines where only one clock is high level and a case where all the clocks in the clock group information 21 are high level while the other clocks are low level. Output signals from the scan enable control signal generation circuit correspond to the clocks. With respect to the clocks with the input signals at high level, the scan enable control signal generation circuit sets to low level all the scan enable control signals 12 corresponding to the related clocks according to the clock relation information 23 and outputs the scan enable control signals 12.

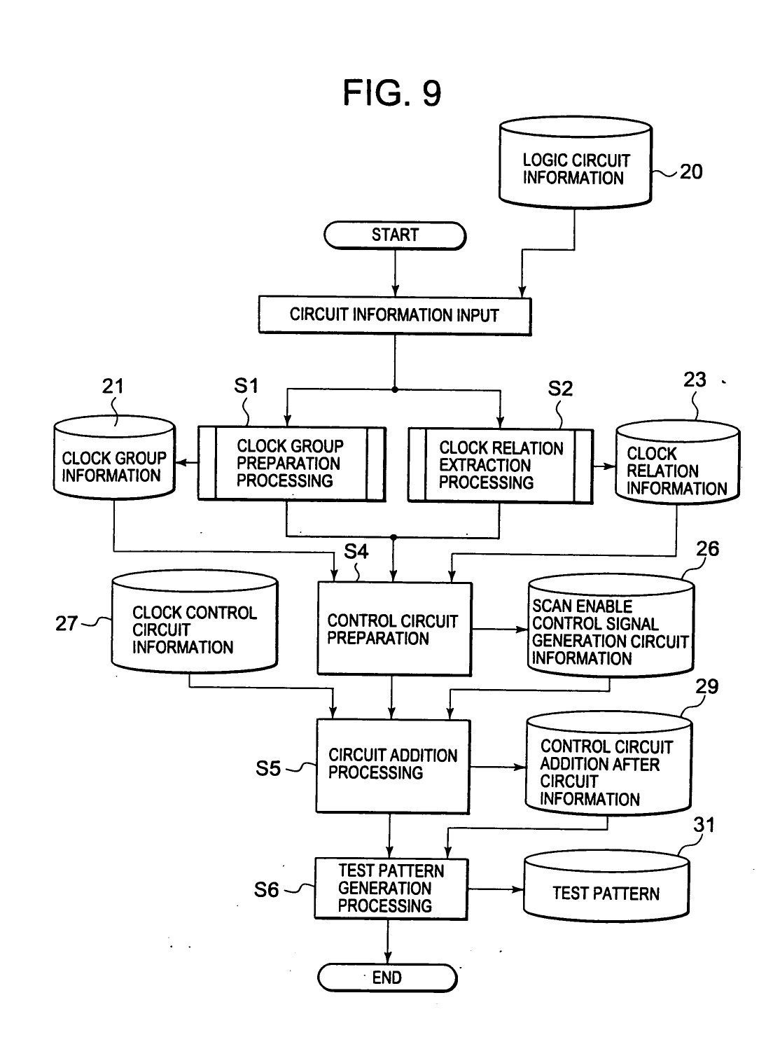

FIG. 9 is a flowchart showing a procedure for test pattern generation processing executed by the test pattern generation tool in the exemplary embodiment. The test pattern generation tool executes readout of the logic circuit information 20 as a preprocessing. In step S1, the test pattern generation tool executes processing (clock group preparation processing) for extracting a combination of the clocks permitted to be simultaneously applied in the same pattern on the basis of the logic circuit information 20. Next, in step S2, the test pattern generation tool executes processing (clock relation extraction processing) for extracting a connection relation in the logic circuit 65 necessary for generation of a test pattern from the input logic circuit information 20 on the basis of the clock signals.

Next, in step S4, the test pattern generation tool executes control circuit preparation processing for preparing a control circuit from the clock relation information 23 and clock group information 21 extracted. In the control circuit preparation processing, the test pattern generation tool recognizes, as combinations of the input signals, a combination in which the clocks belonging to one clock group are high levels, and a combination in which one clock at a time is high level, searches the clock relation information 23 for any of the clocks related to the clock at high level with respect to each combination, and prepares scan enable control signal generation circuit information 26 setting the first scan enable control signal 12a corresponding to the clock concerned to high level.

Subsequently, in step S5, the test pattern generation tool executes circuit addition processing for appending the clock control circuit information 27 and the scan enable control signal generation circuit information 26 to the logic circuit 65 (adding to the circuit) to output control circuit addition after circuit information 29. In step S6, the test pattern generation tool executes automatic test pattern generation processing using the control circuit addition after circuit information 29 obtained as a result of the circuit addition processing, thereby preparing a test pattern 31.

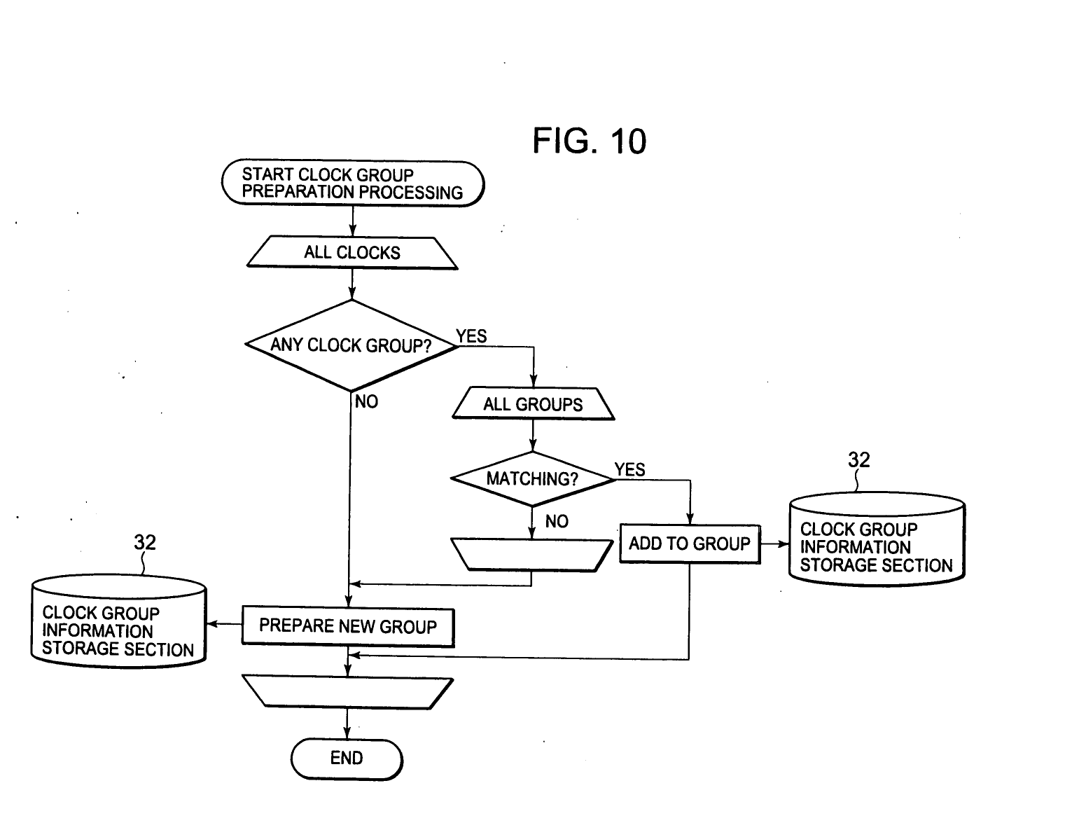

FIG. 10 is a flowchart showing details of a procedure for clock group preparation processing. The test pattern generation tool makes determination with respect to all the clocks existing in the circuit as to whether or not a clock group to which each clock belongs exists. If it is thereby determined that there is no clock group to which the clock belongs, then the test pattern generation tool prepares a new group. If there is a clock group to which the clock belongs, then the test pattern generation tool checks, by using a path analysis function such as a timing analyzer tool, as to whether or not the clock is permitted to be included in the group. If a path exists, then the test pattern generation tool prepares a new group without including the clock in the clock group concerned. If no path exists, then the test pattern generation tool treats the clock in the same clock as a member of the clock group concerned, because no problem of a mislatch due to a clock skew arises even when the clock and the clock group concerned are simultaneously applied. The test pattern generation tool executes this processing with respect to all the clocks.

In the clock group preparation processing, a clock group file is prepared. In the exemplary embodiment, it is assumed that, by step S1 in the flowchart described above, the first scan clock signal CLK1 and the fourth scan clock signal CLK4 or the first scan clock signal CLK1 and the third scan clock signal CLK3 are recognized as a clock group.

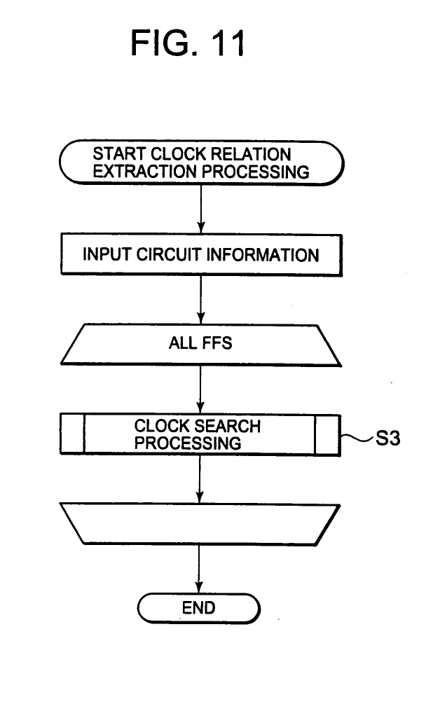

FIG. 11 is a flowchart showing details of a procedure for clock relation extraction processing. In step S3, as shown in FIG. 11, the test pattern generation tool performs clock search processing with respect to all the flip-flops existing in the circuit. By the clock search processing, the test pattern generation tool stores, in a clock group information storage section 32, as clocks relating to each other, the clocks to the flip-flops at starting points of paths having the flip-flop concerned as their terminal points.

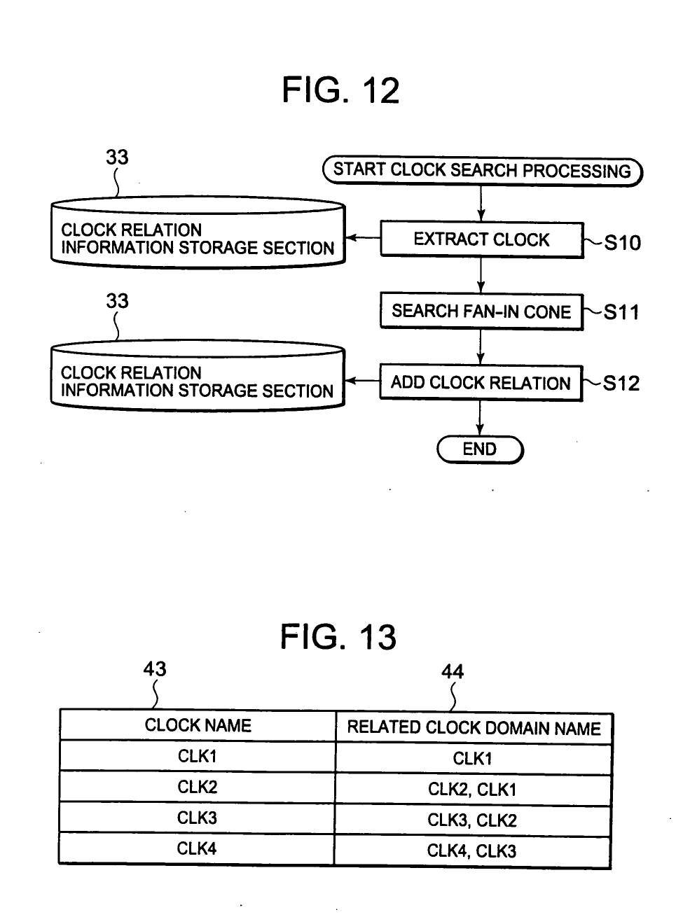

FIG. 12 is a flowchart showing details of a procedure for clock search processing. In step S10, a clock name is extracted by back-tracing from the clock terminal of the flip-flop concerned. At this time a clock signal name concerned is stored as a clock name 43 in the clock relation information storage section 33. Subsequently, in step S11, a fan-in cone of the data input terminal of the flip-flop is extracted. In step S12, with respect to paths having the flip-flop as their terminal points, all the flip-flops at the starting points of the paths are extracted and the names of the clock signals input to the extracted flip-flops are extracted. At this time, the names of the clock signals to the flip-flops in the extracted fan-in cone are stored in the clock relation information storage section 33 as clock domain names 44 related to the clock name 43 concerned.

FIG. 13 is a table showing a configuration of clock relation information 23 usable in the exemplary embodiment. In the clock relation information 23, the clock name 43 and related clock domain names 44 are comparably held. In clock relation extraction processing (step S2), the clocks to the flip-flops existing in the circuit of the fan-in cone of the flip-flop operating by each clock are extracted. There is no clock signal related to the first scan clock signal CLK1. The second scan clock signal CLK2 is related to the first scan clock signal CLK1. The third scan clock signal CLK3 is related to the second scan clock signal CLK2. The fourth scan clock signal CLK4 is related to the third scan clock signal CLK3. This indicates that when the region of the first combination circuit 39 is tested, testing is performed by using the values of the first flip-flop group 34 operating by the first scan clock signal CLK1 and the values of the second flip-flop groups 35 operating by the second scan clock signal CLK2.

By using the clock relation information 23 with respect to the combinations of the clocks used in the test pattern, a scan enable control signal generation circuit 13 is prepared such that the first scan enable control signal 12a, the second scan enable control signal 12b and the third scan enable control signal 12c corresponding to the clocks are high level. Also, in the case of the circuit shown above in FIG. 3, the combinations of the clocks used by the test pattern generation tool are those in which the first scan clock signal CLK1 and the fourth scan clock signal CLK4 or the first scan clock signal CLK1 and the third scan clock signal CLK3 as a clock group are high level, and those in which only one of the first scan clock signal CLK1, the second scan clock signal CLK2, the third scan clock signal CLK3 and the fourth scan clock signal CLK4 is high level. A scan enable control signal generation circuit 13 which, with respect to these input combinations, sets the corresponding enable signals to high level according to the clock relation information 23 is prepared.

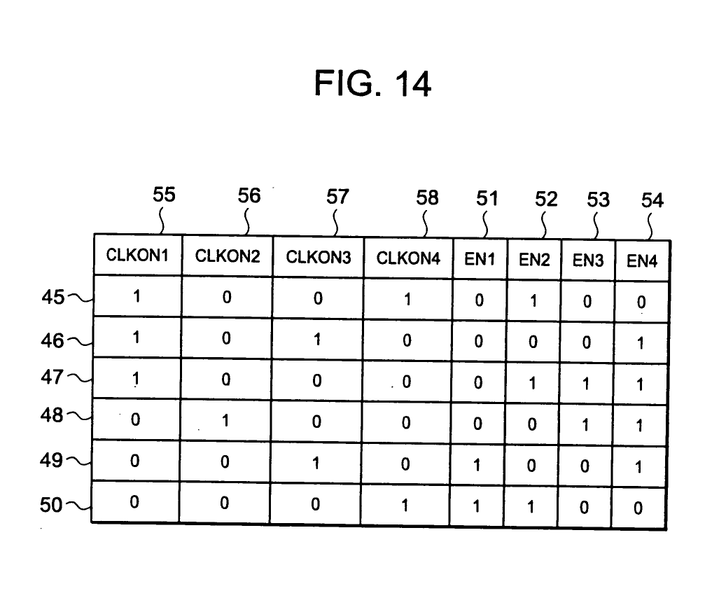

FIG. 14 is a truth table corresponding to the operation of the scan enable control signal generation circuit 13 usable in the exemplary embodiment. Rows respectively correspond to the combinations of clock applications in the test pattern. The fifth column 55 shows first clock-on information CLKON1, which is clock-on information on the first scan clock signal CLK1. Similarly, the sixth column 56 shows second clock-on information CLKON2, which is clock-on information on the second scan clock signal CLK2, the seventh column 57 shows third clock-on information CLKON3, which is clock-on information on the third scan clock signal CLK3, and the eighth column 58 shows fourth clock-on information CLKON4, which is clock-on information on the fourth scan clock signal CLK4.

The first column 51 shows the state of the first scan enable control signal 12a input to the clock control circuit (first clock control circuit 80a) corresponding to the first scan clock signal CLK1. Similarly, the second column 52 shows the state of the second scan enable control signal 12b input to the clock control circuit (second clock control circuit 80b) corresponding to the second scan clock signal CLK2, the third column 53 shows the state of the third scan enable control signal 12c input to the clock control circuit (third clock control circuit 80c) corresponding to the third scan clock signal CLK3, and the fourth column 54 shows the state of the fourth scan enable control signal 12d input to the clock control circuit (fourth clock control circuit 80d) corresponding to the fourth scan clock signal CLK4.

The first row 45 shows the clock combination in the test pattern in the case of application of the first scan clock signal CLK1 and the fourth scan clock signal CLK4. Referring to the clock relation information 23 shown above, the first scan clock signal CLK1 is associated as related clock domain name 44 with the first scan clock signal CLK1. The fourth scan clock signal CLK4 and the third scan clock signal CLK3 are associated as related clock domain name 44 with the fourth scan clock signal CLK4. Referring to the first row 45 in FIG. 14, with respect to this case, “0” is entered in the third column 53 and semiconductor integrated circuit 1 is entered in the second column 52.

The scan enable control signal generation circuit 13 does not control the third scan enable control signal 12c but controls the second scan enable control signal 12b on the basis of the information obtained from this table. Similarly, the second row 46 shows the test pattern in the case of application of the first scan clock signal CLK1 and the third scan clock signal CLK3. Referring to the clock relation information 23 shown above, “1” is entered only in the fourth column 54. The scan enable control signal generation circuit 13 controls the fourth scan enable control signal 12d according to this information. The third to sixth rows 47 to 50 show the cases where only one clock is applied. By referring to the clock relation information 23 shown above with respect to each case, the value of the first scan enable control signal 12a, the second scan enable control signal 12b or the third scan enable control signal 12c is determined. The test circuit 70 has the scan enable control signal generation circuit 13 operating like this, the first clock control circuit 80a, the second clock control circuit 80b, the third clock control circuit 80c and the fourth clock control circuit 80d.

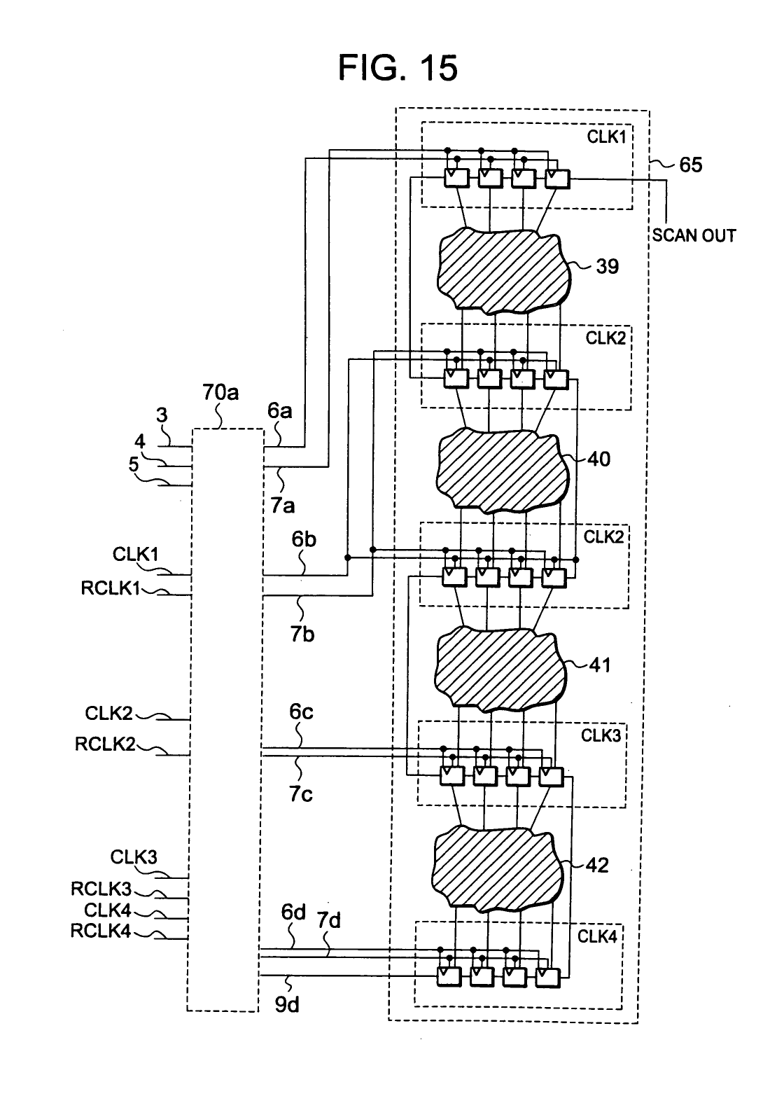

FIG. 15 is a circuit diagram showing connections between the test circuit 70 and the logic circuit 65. When a test in the exemplary embodiment is executed, a pattern may be prepared by the automatic test pattern generation tool for this circuit configuration in FIG. 15.

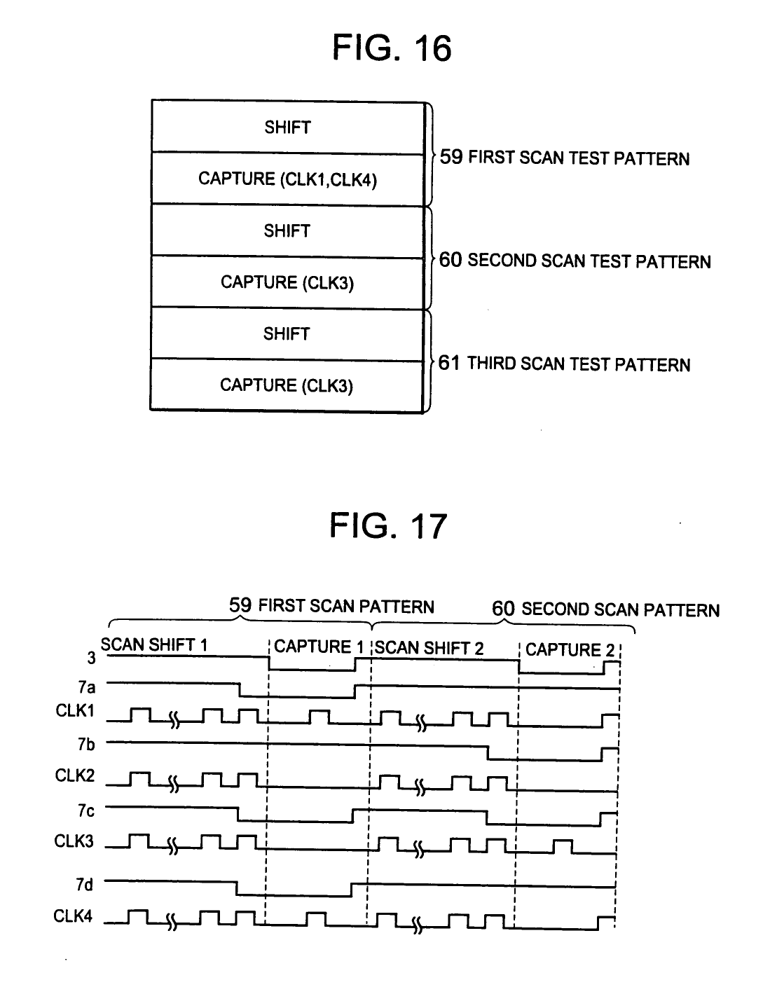

FIG. 16 is a diagram showing a configuration of scan patterns when the test pattern preparation method in the exemplary embodiment is applied to the circuit shown in FIG. 15. As shown in FIG. 16, a first scan pattern 59, a second scan pattern 60 and a third scan pattern 61 in the following description are generated, and description will be made of how the test time is reduced with respect to a test using the patterns.

The automatic test pattern generation tool simultaneously applies the clocks having no connection relationship with each other to prepare a pattern in which a larger number of circuits can be tested with one scan pattern. If some logic circuit exists at an intermediate point with respect to one clock signal, then the state of the logic circuit is set to such a value that the clock signal can pass therethrough.

With respect to the above-described clock control circuits, a pattern is prepared such as to shift in high level to the value of the flip-flop 17 in each clock control circuit when there is a need to apply the clock. When there is no need to apply the clock, the value of the flip-flop 17 is “don't care”. Preferably, don't-care bits are set to low level in advance by instructing the automatic test pattern generation tool to bury don't-care bits at low level.

In the prepared pattern, data output terminals 64 of the scan flip-flops in the logic circuit 65 are controlled by the scan enable input signals 3 output from the clock control circuits. At the time of transition from scan shift to capturing operation, only the circuit region used by the present pattern is made valid. With respect to the regions not used, the states fixed at the time of shifting are maintained, thereby enabling inhibition of switching.

Values used with the first scan pattern 59 are successively loaded from the scan-in terminal into the scan chain. At this time, since with the first scan pattern 59 testing is performed by using the first scan clock signal CLK1 and the fourth scan clock signal CLK4, in the final cycle in scan shifting, values are loaded such that the flip-flops 17 in the first clock control circuit 80a for the first scan clock signal CLK1 and the fourth clock control circuit 80d for the fourth scan clock signal CLK4 are set to high level.

Next, the scan enable control signals 12 are generated in the scan enable control signal generation circuit 13 in the test circuit 70 by using these values. In the first scan pattern 59, since the first scan clock signal CLK1 and the fourth scan clock signal CLK4 are high level, the first scan enable control signal 12a, the third scan enable control signal 12c and the fourth scan enable control signal 12d are low level and the second scan enable control signal 12b is high level.

Subsequently, in the capture cycle, the scan enable input signal 3 is changed from high level (shift mode) to low level (capture mode). Since in the final cycle in scan shifting the first scan enable control signal 12a, the third scan enable control signal 12c and the fourth scan enable control signal 12d are low level and the second scan enable control signal 12b is high level in the second clock control circuit 80b, high level is output as the second scan enable signal 7b from the second clock control circuit 80b and, with respect to the combination circuits in the second combination circuit 40 and the third combination circuit 41, the data output terminals 64 of the scan flip-flops are maintained in the state of being fixed at high level, as during scan shifting, even though the scan enable input signal 3 is changed to low level. Switching in the second combination circuit 40 and the third combination circuit 41 is thus inhibited.

When the capture operation in the first scan pattern 59 is completed, the scan enable input signal 3 is changed from low level to high level and the data outputs from all the scan flip-flops in the logic circuit 65 are in the state of being fixed to high level. In this state, the second scan pattern 60 is shifted in and loaded into the scan flip-flops of the logic circuit 65.

With the second scan pattern 60, the third scan clock signal CLK3 is applied to perform testing on the region of the third combination circuit 41. In the final cycle of scan shifting, therefore, values are loaded such that the flip-flop 17 of the third clock control circuit 80c for the third scan clock signal CLK3 is set to high level. Next, by using these values, the scan enable control signals are generated in the scan enable control signal generation circuit 13. With the second scan pattern 60, since the third scan clock signal CLK3 is high level, the second scan enable control signal 12b and the third scan enable control signal 12c are low level and the first scan enable control signals 12a and 12d are high level. In the capture cycle, the scan enable input signal 3 is changed from high level (shift mode) to low level (capture mode).

In this case, high level is output as the first scan enable signal 7a from the first clock control circuit 80a to which the first scan enable control signal 12a is input and as the fourth scan enable signal 7d from the fourth clock control circuit 80d to which the fourth scan enable control signal 12d is input, even though the scan enable input signal 3 is changed to low level. With respect to the combination circuits in the first combination circuit 39, the data output terminals 64 of the scan flip-flops are maintained in the state of being fixed at high level, as during scan shifting, and the combination circuits in the first combination circuit 39 are not switched.

FIG. 17 is a timing chart of the first scan pattern 59 and the second scan pattern 60. In the first scan pattern 59, the first scan enable signal 7a, the third scan enable signal 7c and the fourth scan enable signal 7d are changed to low level by the final clock in scan shifting. The scan enable input signal 3 is made valid. Only the second scan enable signal 7b is high level, as it is at the time of shifting. The second scan enable signal 7b is high level irrespective of the value of the scan enable input signal 3, and switching in the fan-out cone of the flip-flop to which the scan enable signal 7b is connected is inhibited.

In the second scan pattern 60, the first scan enable signal 7a and the fourth scan enable signal 7d are also fixed at high level at the time of capturing, thereby inhibiting switching in the fan-out cone of the flip-flop to which the signal is supplied. In the field of test pattern generation achieving a reduction in peak power consumption, the semiconductor integrated circuit and the test pattern design method for the semiconductor integrated circuit in the exemplary embodiment are capable of hold-canceling the data output terminals of the scan flip-flops included in the logic circuit in the clock lines used in patterns with respect to each test pattern at the time of transition from the scan shift operation during which the data output terminals of the scan flip-flops are fixed to the capture operation, and maintaining, in the state of being fixed at the time of shifting, the data output terminals of the logic circuit in the clock lines not used. The effect of achieving a reduction in number of cycles in the capture period in scan testing is thus obtained.

The embodiment of the present invention has been concretely described. The invention in the present application is not limited to the above-described embodiment. Various changes can be made therein without departing from the gist of the invention.

Further, it is noted that Applicant's intent is to encompass equivalents of all claim elements, even if amended later during prosecution.

What is claimed is:

1. A semiconductor integrated circuit comprising:
a logic circuit having a plurality of scan path flip-flops constituting a scan path; and
a test circuit which executes a scan path test in correspondence with the scan path,
wherein the test circuit includes:
a first clock control circuit which controls a scan clock;
a second clock control circuit; and
a scan enable control signal generation circuit which supplies a scan enable control signal for controlling a scan enable signal, based on a clock-on information signal output from the first clock control circuit,
wherein the second clock control circuit identifies a value of the scan enable signal on a basis of the scan enable control signal, and
wherein the scan path flip-flops receive the scan clock and the scan enable signal to output fixed values from data output terminals according to the value of the scan enable signal.

2. The semiconductor integrated circuit according to claim 1, wherein one of the first and second clock control circuits includes a clock gating circuit having a flip-flop, a level latch and an AND circuit, and
wherein the clock gating circuit variably sets a level of an output signal in response to a scan shift operation and outputs the set value as the clock-on information signal to the scan enable control signal generation circuit.

3. The semiconductor integrated circuit according to claim 2, wherein the scan enable control signal generation circuit extracts a particular scan clock and outputs a scan enable control signal inactivating another scan clock related to the particular scan clock.

4. A method of generating a test pattern by a computer, comprising:
a logic circuit information readout step of reading out a logic circuit information showing a configuration of a logic circuit included in a semiconductor integrated circuit; and
a test pattern generation step of generating a test pattern for testing the semiconductor integrated circuit on a basis of the logic circuit information,
wherein the test pattern generation step includes:
(a) generating a test circuit information showing a test circuit which executes a scan test on the logic circuit; and
(b) automatically generating the test pattern on a basis of the test circuit information, and
the step (a) includes:
reading out a clock control circuit information showing a clock control circuit which controls a scan clock to be supplied to the logic circuit;
reading out a scan enable control signal generation circuit information showing a scan enable control signal generation circuit which generates a scan enable control signal for controlling a scan enable signal and supplies the scan enable control signal to the clock control circuit; and
generating the test circuit information on a basis of the clock control circuit information and the scan enable control signal generation circuit information.

5. The test pattern generation method according to claim 4, wherein the step (b) includes:
preparing, as the test pattern, a pattern by which a plurality of scan clocks independent of each other are simultaneously applied; and
setting a state of a particular logic circuit, if any, existing at an intermediate position in a path through which the scan clock passes to such a value that the scan clock can pass.

6. A method of testing a semiconductor integrated circuit by a computer, comprising:
a test pattern generation step of generating a test pattern for testing the semiconductor integrated circuit; and
a test step of executing a scan test on the semiconductor integrated circuit by using the test pattern,
wherein the test pattern generation step includes:
(a) generating a test circuit information showing a test circuit which executes a scan test on a logic circuit constituting the semiconductor integrated circuit; and
(b) automatically generating the test pattern on a basis of the test circuit information, and
the test step includes:
(c) outputting a clock-on information signal from a clock control circuit which controls a scan clock to be supplied to the logic circuit;
(d) receiving the clock-on information and generating a scan enable control signal to be supplied to another clock control circuit;
(e) identifying a value of a scan enable signal for the other clock control circuit on a basis of the scan enable control signal; and
(f) allowing a scan path flip-flop included in the logic circuit to receive the scan clock and the scan enable signal and output a fixed value from a data output terminal according to the value of the scan enable signal.

7. The method according to claim 6, wherein the step (a) includes:
reading out a clock control circuit information showing the clock control circuit;
reading out a scan enable control signal generation circuit information showing a scan enable control signal generation circuit which generates a scan enable control signal for controlling a scan enable signal and supplies the scan enable control signal to the clock control circuit; and
generating the test circuit information on a basis of the clock control circuit information and the scan enable control signal generation circuit information.

8. The method according to claim 7, wherein the step (b) includes:
preparing, as the test pattern, a pattern by which a plurality of scan clocks independent of each other are simultaneously applied; and
setting the state of a particular logic circuit, if any, existing at an intermediate position in a path through which the scan clock passes to such a value that the scan clock can pass.

9. A method of designing a semiconductor integrated circuit, comprising:
a logic circuit information readout step of reading out a logic circuit information showing a configuration of a logic circuit included in the semiconductor integrated circuit; and
a test circuit information generation step of generating a test circuit information showing a configuration of a test circuit which executes a scan path test,
wherein the test circuit information generation step includes:
(a) reading out a clock control circuit information showing a clock control circuit which controls a scan clock used in the scan path test; and
(b) generating a scan enable control signal generation circuit information showing a scan enable control signal generation circuit which generates a scan enable control signal for controlling a scan enable signal to be supplied to the clock control circuit, and
the step (b) includes:
a clock group information generation step of generating, on a basis of the logic circuit information, clock group information by extracting a combination of scan clocks which can be simultaneously applied in one pattern;
a clock relation information generation step of generating, on a basis of the logic circuit information, clock relation information by extracting a connection relation in the logic circuit necessary for generation of a test pattern; and
a control circuit preparation step of generating the scan enable control signal generation circuit information on a basis of the clock group information and the clock relation information.

10. The method according to claim 9, wherein the control circuit preparation step includes:
extracting a particular scan clock and extracting another scan clock related to the particular scan clock as a related scan clock from the clock relation information; and
generating the scan enable control signal generation circuit information so that a scan enable control signal inactivating the related scan clock is output.
